(19) United States
(12) Patent Application Publication
(10) Pub. No.: US 2025/0167065 A1
(43) Pub. Date: May 22, 2025

(54) SEMICONDUCTOR PACKAGE INCLUDING HEAT DISSIPATION MEMBER, AND METHOD FOR MANUFACTURING THE SAME

(71) Applicant: SK hynix Inc., Icheon-si Gyeonggi-do (KR)

(72) Inventor: Jun Young KIM, Icheon-si Gyeonggi-do (KR)

(73) Assignee: SK hynix Inc., Icheon-si Gyeonggi-do (KR)

(21) Appl. No.: 18/617,147

(22) Filed: Mar. 26, 2024

(30) Foreign Application Priority Data
Nov. 20, 2023 (KR) 10-2023-0161079

(51) Int. Cl. H01L 23/367; H01L 23/00; H01L 23/31; H01L 23/373; H01L 23/544; H01L 25/00; H01L 25/065

(52) U.S. Cl. CPC H01L 23/3672; H01L 21/4871; H01L 23/3128; H01L 23/3735; H01L 23/544; H01L 24/19; H01L 24/20; H01L 24/32; H01L 24/96; H01L 24/48; H01L 24/73; H01L 24/95; H01L 25/0657; H01L 2223/54486; H01L 2224/19; H01L 2224/214; H01L 2224/32145; H01L 2224/32245; H01L 2224/48225; H01L 2224/73265; H01L 2224/95001; H01L 2224/96; H01L 2225/0651; H01L 2225/06562; H01L 2924/1815

(57) ABSTRACT

A semiconductor package includes a heat dissipation member having a plurality of through holes which pass through a first surface of the heat dissipation member. The semiconductor package also includes a semiconductor chip disposed on the first surface of the heat dissipation member and a vertical connector connected to the semiconductor chip. The semiconductor package further includes a molding member sealing the semiconductor chip, sealing the vertical connector, and filling the plurality of through holes. The semiconductor package additionally includes a redistribution layer disposed on the molding member.

### CROSS-REFERENCE TO RELATED APPLICATION

The present application claims priority under 35 U.S.C. § 119 (a) to Korean Patent Application No. 10-2023-0161079 filed in the Korean Intellectual Property Office on Nov. 20, 2023, which is incorporated herein by reference in its entirety.

### BACKGROUND

### 1. Technical Field

Various embodiments of the disclosed technology generally relate to a semiconductor package including a heat dissipation member and a method for manufacturing the same.

### 2. Related Art

An electronic product is increasingly required to process high-capacity data even while being decreased in volume. Accordingly, there is a growing need to increase the degree of integration of a semiconductor device used in the electronic product.

As the degree of integration of the semiconductor device increases, heat generated during the operation of the semiconductor device may adversely affect the operation of the element of a semiconductor chip.

### SUMMARY

In an embodiment, a semiconductor package may include: a heat dissipation member having a plurality of through holes which pass through a first surface of the heat dissipation member; a semiconductor chip disposed on the first surface of the heat dissipation member; a vertical connector connected to the semiconductor chip; a molding member sealing the semiconductor chip, sealing the vertical connector, and filling the plurality of through holes; and a redistribution layer disposed on the molding member.

In an embodiment, a method for manufacturing a semiconductor package may include: forming, on a carrier substrate, a heat dissipation member having a plurality of through holes; disposing a semiconductor chip on the heat dissipation member; forming a vertical connector connected to the semiconductor chip; forming a molding member which seals the semiconductor chip and the vertical connector and fills the plurality of through holes; and forming a redistribution layer on the molding member.

### BRIEF DESCRIPTION OF THE DRAWINGS

FIG. 1 is a cross-sectional view of a semiconductor package based on an embodiment of the disclosed technology.

FIG. 2 is a plan view illustrating a heat dissipation member and a fiducial mark of the semiconductor package based on the embodiment of the disclosed technology.

FIG. 3 is a cross-sectional view of a semiconductor package based on an embodiment of the disclosed technology.

FIGS. 4 to 11 are views illustrating a method for manufacturing a semiconductor package based on an embodiment of the disclosed technology.

### DETAILED DESCRIPTION

Hereinafter, some embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence, or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled,” or “linked” with each other.

In descriptions for time flow relationships of components, an operating method or a fabricating method, in the case where pre and post relationships in terms of time or pre and post relationships in terms of flow are described, for example, by “after,” “following,” “next,” or “before,” non-continuous cases may be included unless “immediately” or “directly” is used.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings. Various embodiments are directed to providing a semiconductor package including a heat dissipation member and a method for manufacturing the same. According to some embodiments of the disclosed technology, it is possible to provide a semiconductor package including a heat dissipation member which has a plurality of through holes filled with a molding member, and a method for manufacturing the same.

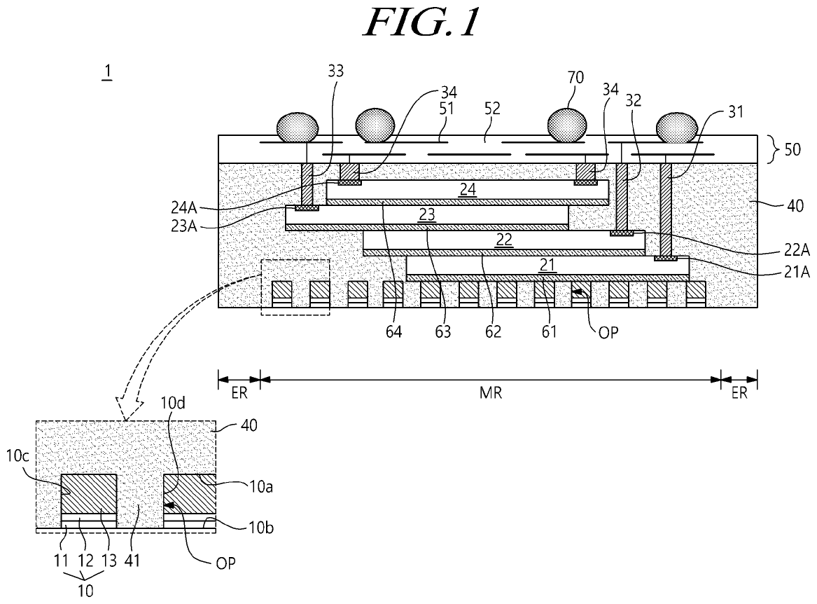

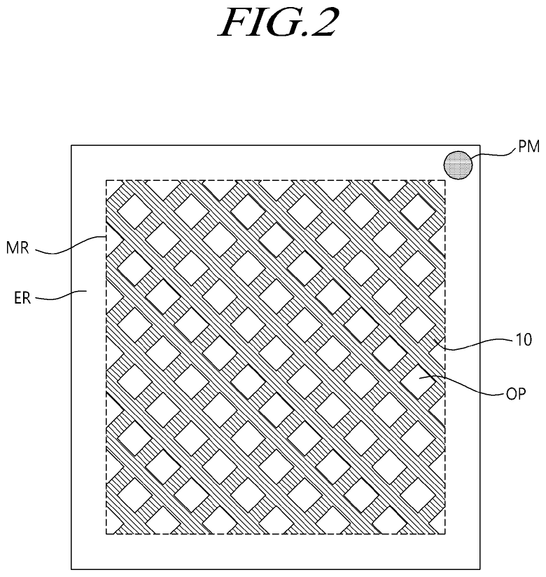

FIG. 1 is a cross-sectional view of a semiconductor package based on an embodiment of the disclosed technology, and FIG. 2 is a plan view illustrating a heat dissipation member and a fiducial mark of the semiconductor package based on the embodiment of the disclosed technology.

Referring to FIGS. 1 and 2, a semiconductor package 1 may include a mounting region MR and a peripheral region ER around the mounting region MR. The peripheral region ER may surround the outer edge of the mounting region MR.

A heat dissipation member 10 may be disposed in the mounting region MR, and may include a plurality of through holes OP which pass through one surface 10a. For example, the through holes OP may extend from the one surface 10a to the other surface 10b of the heat dissipation member 10, and may pass through the other surface 10b. The other surface 10b of the heat dissipation member 10 may be a surface which is opposite to the one surface 10a. The other surface 10b of the heat dissipation member 10 may be a surface which is located farther away from a first semiconductor chip 21 than the one surface 10a. The one and other surfaces 10a and 10b of the heat dissipation member 10 are also referred to as the first and second, respectively, surfaces 10a and 10b of the heat dissipation member 10. The heat dissipation member 10 may have a mesh structure which has the plurality of through holes OP.

As illustrated in FIG. 2, the through holes OP may have a rhombus shape. Although not illustrated, the through holes OP may have a polygonal shape such as a triangle, a rectangle, a square, or a pentagon, or may have a circular or elliptical shape. Although FIG. 2 illustrates a case where the through holes OP are regularly disposed, the through holes OP may be irregularly disposed.

The heat dissipation member 10 may include a material with a greater Young's modulus than a molding member 40 which will be described later. The heat dissipation member 10 may be made of metal.

The heat dissipation member 10 may have a structure in which a barrier metal layer 11, a seed metal layer 12, and a plated metal layer 13 are stacked. The seed metal layer 12 may be disposed on the barrier metal layer 11, and the plated metal layer 13 may be disposed on the seed metal layer 12. The barrier metal layer 11, the seed metal layer 12, and the plated metal layer 13 may have the same layout structure.

For example, the seed metal layer 12 and the plated metal layer 13 may include the same material. The seed metal layer 12 and the plated metal layer 13 may include copper (Cu). The barrier metal layer 11 may include metal with a lower ionization tendency than the plated metal layer 13. For example, the barrier metal layer 11 may include at least one of Titanium (Ti), titanium-tungsten (TiW), and Nickel (Ni). A metal having a lower ionization tendency refers to the metal having a more stable electronic configuration and thus a higher ionization energy.

The upper surface of the plated metal layer 13 may configure the one surface 10a of the heat dissipation member 10, and the lower surface of the barrier metal layer 11 may configure the other surface 10b of the heat dissipation member 10. The upper surface of the plated metal layer 13 is covered with the molding member 40 and is not exposed to the outside of the semiconductor package 1, but the lower surface of the barrier metal layer 11 is exposed to the outside of the semiconductor package 1. As the barrier metal layer 11 which has a surface exposed to the outside of the semiconductor package 1 is made of metal with a low ionization tendency, oxidation of the heat dissipation member 10 may be suppressed.

First to fourth semiconductor chips 21 to 24 may be stacked on the one surface 10a of the heat dissipation member 10.

Each of the first to fourth semiconductor chips 21 to 24 may include nonvolatile memory such as flash memory, PRAM (phase-change random-access memory), and MRAM (magnetoresistive random-access memory), or volatile memory such as DRAM (dynamic random-access memory) and SRAM (static random-access memory), or non-memory such as a logic circuit, but is not limited thereto.

Each of the first to fourth semiconductor chips 21 to 24 may have a front side on which a chip pad (one of 21A to 24A) is disposed and a back side which faces oppositely to the front side. The chip pad (one of 21A to 24A) may be electrically connected to an integrated circuit in the semiconductor chip (one of 21 to 24).

The first to fourth semiconductor chips 21 to 24 may be stacked on the heat dissipation member 10 in a face-up type so that the back sides thereof face the heat dissipation member 10.

First to fourth adhesive layers 61 to 64 may be attached to the back sides, respectively, of the first to fourth semiconductor chips 21 to 24. Each of the first to fourth semiconductor chips 21 to 24 may be attached to the semiconductor chip (one of 21 to 23) or the heat dissipation member 10 which is located immediately thereunder, using the adhesive layer (one of 61 to 64). The first to fourth semiconductor chips 21 to 24 may be offset-stacked on each other to expose the respective chip pads 21A to 24A.

Although FIG. 1 illustrates an embodiment where the four semiconductor chips 21 to 24 are stacked on the heat dissipation member 10, this is nothing but a mere example, and the disclosed technology is not limited thereto. The disclosed technology includes all embodiments where at least one semiconductor chip is disposed on the heat dissipation member 10.

First to fourth vertical connectors 31 to 34 may be connected to the first to fourth semiconductor chips 21 to 24, respectively.

Each of the first to fourth vertical connectors 31 to 34 may extend in a vertical direction with one end thereof connected to a corresponding one of the chip pads 21A to 24A of the first to fourth semiconductor chips 21 to 24. The first to fourth vertical connectors 31 to 34 may be configured with interconnection members which extend substantially vertically or are erected substantially vertically from the surfaces of the first to fourth semiconductor chips 21 to 24.

The first to fourth vertical connectors 31 to 34 may provide paths through which electrical signals are transmitted to the first to fourth semiconductor chips 21 to 24, respectively. The first to fourth vertical connectors 31 to 34 may be formed of one or more conductive metals, such as gold (Au) or copper (Cu), for example.

The first to fourth vertical connectors 31 to 34 may be vertical bonding wires. Alternatively, among the first to fourth vertical connectors 31 to 34, the fourth vertical connector 34 connected to the fourth semiconductor chip 24 located uppermost may be a conductive bump, and the first to third vertical connectors 31 to 33 connected to the first to third semiconductor chips 21 to 23 excluding the fourth semiconductor chip 24 may be vertical bonding wires.

The molding member 40 is formed to cover the one surface 10a of the heat dissipation member 10, fill the through holes OP of the heat dissipation member 10, and cover the first to fourth semiconductor chips 21 to 24 and the first to fourth vertical connectors 31 to 34. The molding member 40 may serve to seal the first to fourth semiconductor chips 21 to 24 and the first to fourth vertical connectors 31 to 34 to protect the first to fourth semiconductor chips 21 to 24 and the first to fourth vertical connectors 31 to 34 from an external environment. The molding member 40 may include an encapsulant material such as an epoxy molding compound (EMC) material. The encapsulant material may include, for example, an epoxy resin component and fillers dispersed therein.

As the molding member 40 fills the through holes OP of the heat dissipation member 10, the heat dissipation member 10 may be combined with the molding member 40.

The heat dissipation member 10 combined with the molding member 40 may serve as a protective layer 10 and 40 which protects the first to fourth semiconductor chips 21 to 24 and the first to fourth vertical connectors 31 to 34. As the heat dissipation member 10 is combined with the molding member 40, the volume fraction occupied by the molding member 40 in the semiconductor package 1 may decrease. As described above, because the heat dissipation member 10 may be made of a material with a greater Young's modulus than the molding member 40, the heat dissipation member 10 may serve to increase the body strength of the protective layer 10 and 40.

The molding member 40 may include protrusions 41 which fill the through holes OP. Inner side surfaces 10d of the heat dissipation member 10 which are provided by the through holes OP may contact the protrusions 41 of the molding member 40.

The inner side surfaces 10d of the heat dissipation member 10 may be surfaces which are positioned in the through holes OP. In the disclosed technology, the through holes OP may pass through the one surface 10a and the other surface 10b of the heat dissipation member 10, and the inner side surfaces 10d of the heat dissipation member 10 may be surfaces which connect the one surface 10a and the other surface 10b. The ends of the protrusions 41 of the molding member 40 may be disposed on the same plane as the other surface 10b of the heat dissipation member 10. The molding member 40 might not extend to the other surface 10b of the heat dissipation member 10.

By forming the plurality of through holes OP in the heat dissipation member 10 and filling the through holes OP of the heat dissipation member 10 with the molding member 40, the contact area between the molding member 40 and the heat dissipation member 10 may increase. Accordingly, stress caused by a difference in properties such as ductility and thermal expansion coefficient between a material configuring the heat dissipation member 10 and a material configuring the molding member 40 may be mitigated or alleviated. Therefore, it is possible to mitigate, suppress, or prevent a delamination or/and a crack from occurring at the interface between the heat dissipation member 10 and the molding member 40 due to the stress.

The molding member 40 may be configured to surround outer side surfaces 10c of the heat dissipation member 10. The outer side surfaces 10c of the heat dissipation member 10 may be surfaces which connect the outer edge of the one surface 10a and the outer edge of the other surface 10b. The heat dissipation member 10 might not be disposed on the side surfaces of the molding member 40. The side surfaces of the molding member 40 may be surfaces which are cut in a sawing process that individualizes the semiconductor package 1. Because the heat dissipation member 10 is not disposed on the surfaces which are cut in the sawing process, a stress applied to a material during the sawing process may decrease, and it is possible to mitigate, suppress, or prevent the occurrence of a burr.

A redistribution layer 50 is provided on the molding member 40. The redistribution layer 50 may include redistribution lines 51 and a dielectric layer 52. The redistribution lines 51 may be connected to the vertical connectors 31 to 34 and may be connected to the semiconductor chips 21 to 24 through the vertical connectors 31 to 34. The redistribution lines 51 may be insulated from each other by the dielectric layer 52.

External connection terminals 70 may be connected to some of the redistribution lines 51. Although not illustrated, some of the redistribution lines 51 may include ball lands. The dielectric layer 52 may have openings which expose the ball lands. The external connection terminals 70 may be attached to the ball lands. The external connection terminals 70 may include solder balls.

As illustrated in FIG. 2, a fiducial mark PM may be disposed in the peripheral region ER. The fiducial mark PM may be used as a reference point (e.g., a zero point) for determining the positions of the first to fourth semiconductor chips 21 to 24 in a process of disposing the first to fourth semiconductor chips 21 to 24.

Although not illustrated in the drawings, the fiducial mark PM may be disposed at the same height level as the plated metal layer 13 of the heat dissipation member 10. The fiducial mark PM may be formed together with the plated metal layer 13 of the heat dissipation member 10 and may be made of the same material as the plated metal layer 13, but is not limited thereto. The fiducial mark PM may be formed in a separate process from the plated metal layer 13, or it may be made of a different material from the plated metal layer 13. Although FIG. 2 illustrates a case where the fiducial mark PM is disposed in the peripheral region ER, the position of the fiducial mark PM is not limited thereto.

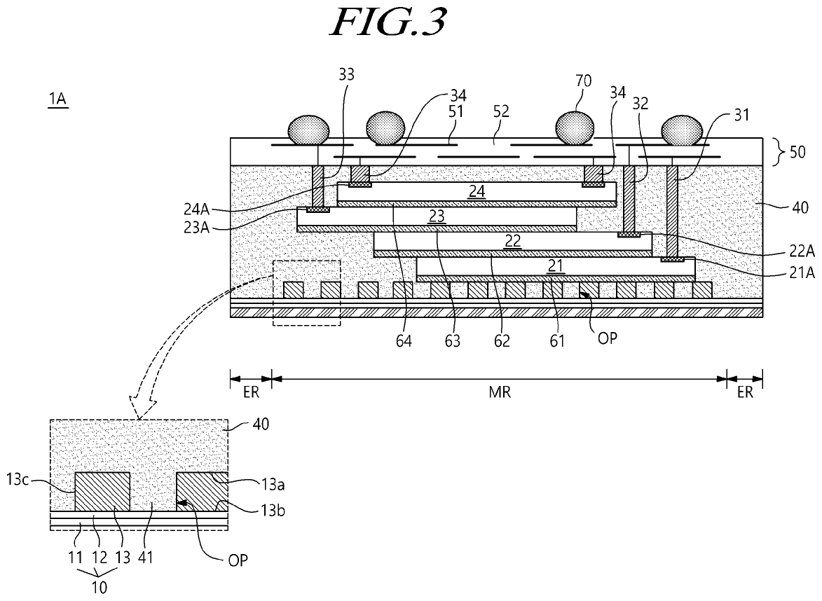

FIG. 3 is a cross-sectional view of a semiconductor package based on an embodiment of the disclosed technology.

Referring to FIG. 3, the through holes OP of the heat dissipation member 10 may be formed to a depth that passes through the one surface 10a of the heat dissipation member 10 and does not reach the other surface 10b of the heat dissipation member 10.

The barrier metal layer 11 and the seed metal layer 12 of the heat dissipation member 10 may be disposed in the mounting region MR and the peripheral region ER, and the plated metal layer 13 may be disposed in the mounting region MR. The through holes OP may pass through the plated metal layer 13, but might not pass through the barrier metal layer 11 and the seed metal layer 12. The through holes OP may pass through the plated metal layer 13 to expose the seed metal layer 12. The plated metal layer 13 may have a thickness larger than the sum of the thicknesses of the seed metal layer 12 and the thickness of the barrier metal layer 11.

The molding member 40 may be configured to surround outer side surfaces 13c of the plated metal layer 13. The outer side surfaces 13c may be surfaces which connect the outer edge of a first surface 13a and the outer edge of a second surface 13b of the plated metal layer 13. The first surface 13a of the plated metal layer 13 may be a surface on which the first semiconductor chip 21 is mounted, and the second surface 13b of the plated metal layer 13 may be a surface which is opposite to the first surface 13a. The second surface 13b of the plated metal layer 13 may be a surface which is located farther away from the first semiconductor chip 21 than the first surface 13a and contacts the seed metal layer 12.

The side surfaces of the molding member 40 may be surfaces which are cut in a sawing process that individualizes a semiconductor package 1A. On the side surfaces of the molding member 40, only the barrier metal layer 11 and the seed metal layer 12 of the heat dissipation member 10 might be disposed, and the plated metal layer 13 might not be disposed. Because the plated metal layer 13 which has a relatively large thickness is not disposed on the surfaces which are cut in the sawing process, a stress applied to a material during the sawing process may decrease, and it is possible to mitigate, suppress, or prevent the occurrence of a burr.

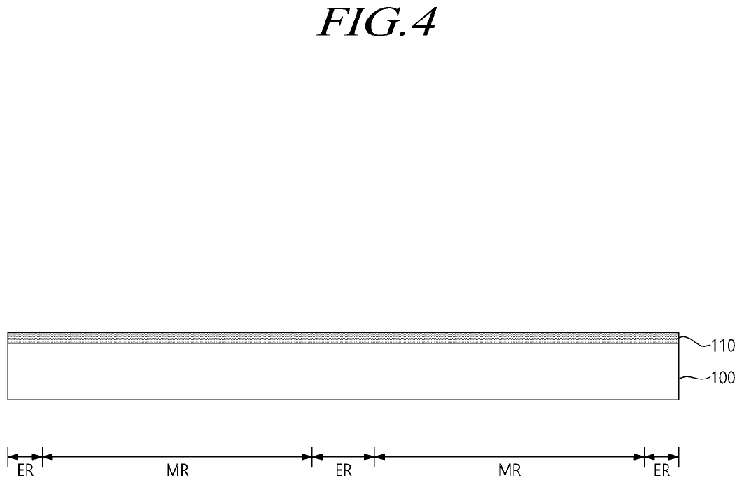

FIGS. 4 to 11 are views illustrating a method for manufacturing a semiconductor package based on an embodiment of the disclosed technology.

Referring to FIG. 4, a carrier substrate 100 is provided.

Process steps for manufacturing a semiconductor package based on an embodiment of the disclosed technology may be performed on the carrier substrate 100. The carrier substrate 100 may serve as a work table, a handling wafer, or a supporting substrate.

The carrier substrate 100 may be made of glass, silicon (Si), or metal. The carrier substrate 100 may have a circular shape such as a wafer.

A debonding layer 110 may be disposed on the carrier substrate 100. The debonding layer 110 may be made of a material which has an adhesion force and whose adhesion force may be reduced by at least one of chemical processing and optical processing. The carrier substrate 100 may be made of a transparent material.

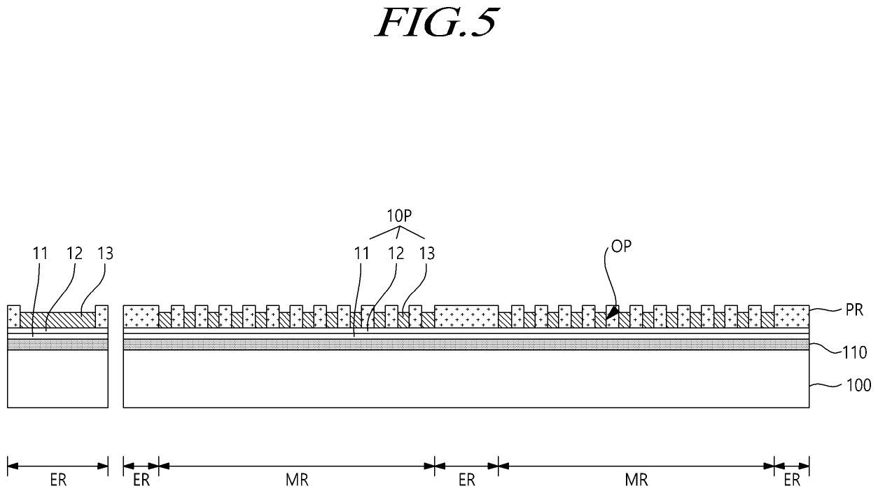

Referring to FIG. 5, a step of forming a heat dissipation member 10P is performed.

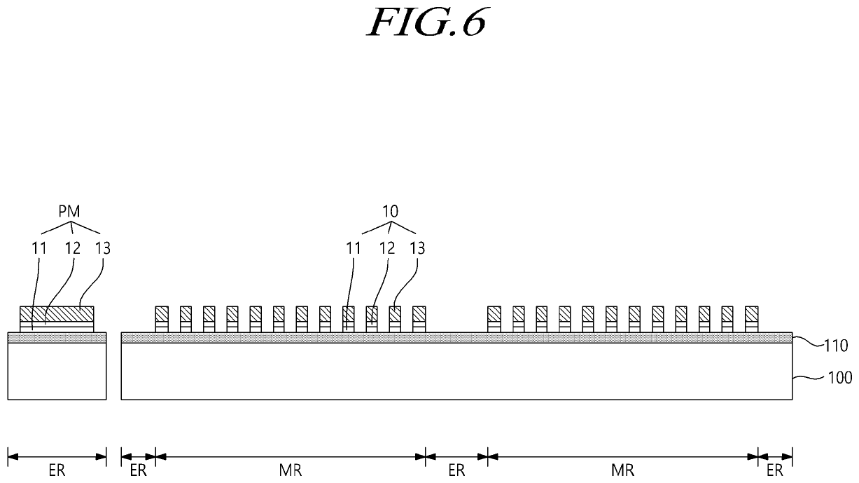

The heat dissipation member 10P may be a pre-structure of a heat dissipation member 10 of FIG. 6. A process for forming the heat dissipation member 10P may include forming a barrier metal layer 11 on the debonding layer 110, forming a seed metal layer 12 on the barrier metal layer 11, forming a mask layer PR having mesh-shaped open regions on the seed metal layer 12, and forming a plated metal layer 13 on the seed metal layer 12 through a plating process.

The barrier metal layer 11 and the seed metal layer 12 may be formed on a mounting region MR and a peripheral region ER. The barrier metal layer 11 may include metal whose ionization tendency is different from metal included in the seed metal layer 12 and the plated metal layer 13. The barrier metal layer 11 may include metal whose ionization tendency is less than metal included in the seed metal layer 12 and the plated metal layer 13. For example, the seed metal layer 12 and the plated metal layer 13 may include copper (Cu), and the barrier metal layer 11 may include at least one of Titanium (Ti), titanium-tungsten (TiW), and Nickel (Ni). The barrier metal layer 11 and the seed metal layer 12 may be formed using electroless plating, evaporation, or sputtering, but are not limited thereto.

The mask layer PR may include a plurality of patterns which are separated by the mesh-shaped open regions. The mask layer PR is patterned to provide open regions which provide a template for the plated metal layer 13. The mask layer PR may cover the peripheral region ER so that the plated metal layer 13 is not formed in the peripheral region ER.

Through a plating process, the plated metal layer 13 is formed on the seed metal layer 12 which is exposed by the open regions of the mask layer PR. The plating process may use an electroless plating process or an electroplating process, but is not limited thereto. The plated metal layer 13 may have the same layout structure as the open regions of the mask layer PR. As a plurality of through holes OP corresponding to the plurality of patterns configuring the mask layer PR are formed in the plated metal layer 13, the plated metal layer 13 may have a mesh-shaped layout structure.

In the drawings of the present specification, it is illustrated that the thickness of the plated metal layer 13 is similar to the sum of the thickness of the barrier metal layer 11 and the thickness of the seed metal layer 12. However, the thickness of the barrier metal layer 11 and the thickness of the seed metal layer 12 are illustrated by being exaggerated, and the thickness of the plated metal layer 13 is larger than the sum of the thickness of the barrier metal layer 11 and the thickness of the seed metal layer 12.

In the process of forming the plated metal layer 13, a fiducial mark PM may be additionally formed together with the plated metal layer 13. The fiducial mark PM may be formed by patterning the mask layer PR to further include an opening region which provides a template for the fiducial mark PM and using the plating process of forming the plated metal layer 13. Meanwhile, for another example, the fiducial mark PM may be formed separately from the plated metal layer 13. A fiducial mark may be formed on the seed metal layer 12 before or after forming the plated metal layer 13.

The mask layer PR may be formed using photoresist, and may be removed after forming the plated metal layer 13.

Referring to FIG. 6, a step of selectively removing portions of the barrier metal layer 11 and the seed metal layer 12 placed outside the plated metal layer 13 is performed.

The barrier metal layer 11 and the seed metal layer 12 are etched using the plated metal layer 13 as an etch mask. Accordingly, the barrier metal layer 11 and the seed metal layer 12 may have substantially the same layout structure as the plated metal layer 13. The barrier metal layer 11 and the seed metal layer 12 may be disposed in the mounting region MR, and the barrier metal layer 11 and the seed metal layer 12 of the peripheral region ER may be removed. The barrier metal layer 11 and the seed metal layer 12 may have a mesh-shaped layout structure. By this fact, the heat dissipation member 10 having a structure in which the barrier metal layer 11, the seed metal layer 12, and the plated metal layer 13 are stacked is formed.

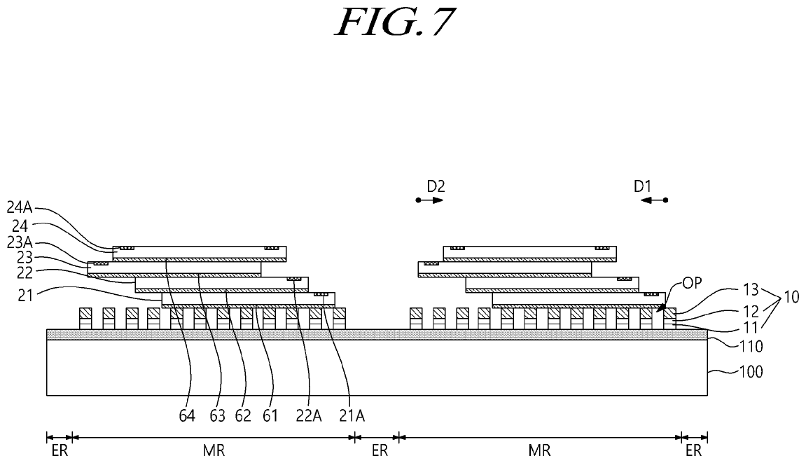

Referring to FIG. 7, a step of disposing first to fourth semiconductor chips 21 to 24 on the heat dissipation member 10 may be performed.

A chip mounter (not illustrated) which is used in the process of disposing the first to fourth semiconductor chips 21 to 24 may recognize the fiducial mark PM (see FIG. 6) before disposing the first to fourth semiconductor chips 21 to 24, and may determine positions where the first to fourth semiconductor chips 21 to 24 should be disposed, by using the recognized fiducial mark PM (see FIG. 6) as a reference point (e.g., a zero point). Accordingly, the first to fourth semiconductor chips 21 to 24 may be disposed accurately at intended positions.

Each of the first to fourth semiconductor chips 21 to 24 may be attached to the semiconductor chip (one of 21 to 23) or the heat dissipation member 10 which is located immediately thereunder, using an adhesive layer (one of 61 to 64).

The first to fourth semiconductor chips 21 to 24 may be offset-stacked on each other to expose chip pads 21A to 24A. For example, the intermediate second and third semiconductor chips 22 and 23 may be offset-stacked in a first offset direction D1 with respect to the lowermost first semiconductor chip 21, and the uppermost fourth semiconductor chip 24 may be offset-stacked in a second offset direction D2 opposite to the first offset direction D1.

As the fourth semiconductor chip 24 is offset-stacked in the second offset direction D2 opposite to the first offset direction D1 being the offset direction of the second and third semiconductor chips 22 and 23, the layout area occupied by the first to fourth semiconductor chips 21 to 24 may be reduced.

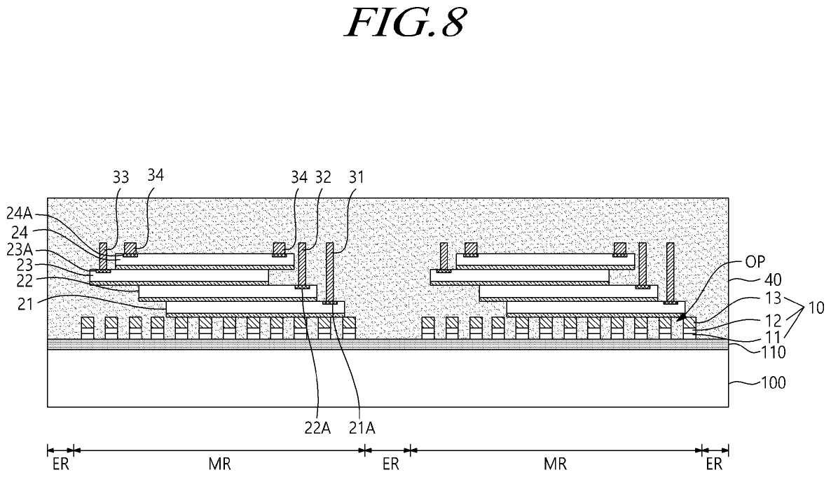

Referring to FIG. 8, a step of forming first to fourth vertical connectors 31 to 34 and a molding member 40 is performed.

The first to fourth vertical connectors 31 to 34 may be formed of a conductive metal material such as gold (Au) or copper (Cu). The first to fourth vertical connectors 31 to 34 may be configured with interconnection members which extend substantially vertically or are erected substantially vertically from the surfaces of the chip pads 21A to 24A of the first to fourth semiconductor chips 21 to 24.

The first to fourth vertical connectors 31 to 34 which are connected to the first to fourth semiconductor chips 21 to 24, respectively, may be formed through a wire bonding process using wire bonding equipment (not illustrated). Alternatively, the first to third vertical connectors 31 to 33 which are connected to the first to third semiconductor chips 21 to 23 may be formed through a wire bonding process using wire bonding equipment, and the fourth vertical connector 34 which is connected to the fourth semiconductor chip 24 may be formed using a bump forming process. That is to say, a conductive bump may be formed on the chip pad 24A of the uppermost fourth semiconductor chip 24 without forming a bonding wire. The conductive bump may include copper (Cu).

The molding member 40 may be formed to cover and encapsulate the first to fourth semiconductor chips 21 to 24 and the first to fourth vertical connectors 31 to 34, cover the one surface of the heat dissipation member 10 and fill the through holes OP of the heat dissipation member 10.

The molding member 40 may be formed through a molding process using a liquid sealant. The molding process may include mounting, in a mold (not illustrated), the carrier substrate 100 which is provided with the first to fourth semiconductor chips 21 to 24 and the first to fourth vertical connectors 31 to 34, pouring the liquid sealant into the mold, pressing the mold, and curing the poured sealant. The sealant may include an EMC (epoxy molding compound).

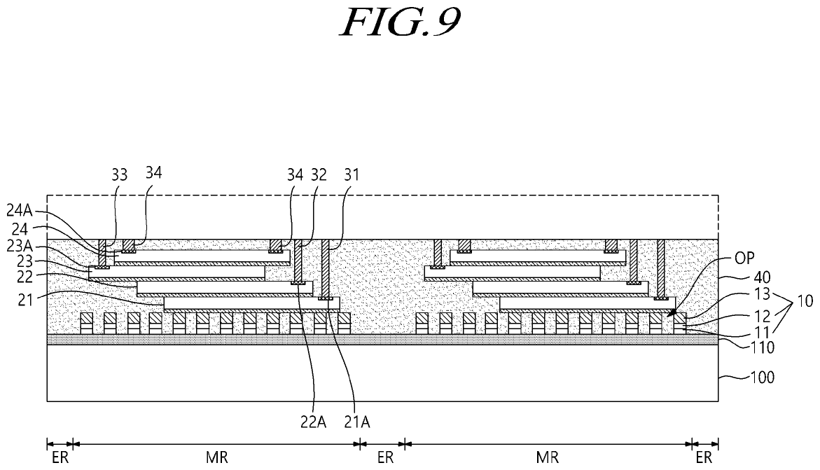

Referring to FIG. 9, a thinning process of reducing the thickness of the molding member 40 may be performed.

The thinning process may include a chemical mechanical polishing (CMP) or grinding process. The upper surface of the molding member 40 may be lowered by the thinning process. As a result of performing the thinning process, the first to fourth vertical connectors 31 to 34 may be exposed on the upper surface of the molding member 40.

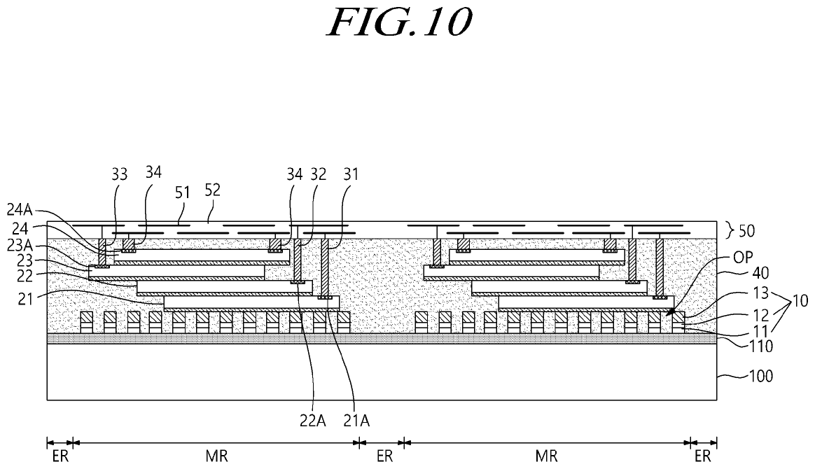

Referring to FIG. 10, a step of forming a redistribution layer 50 may be performed.

The redistribution layer 50 may include redistribution lines 51 and a dielectric layer 52 which insulates the redistribution lines 51 from each other. Some of the redistribution lines 51 may be connected to the first to fourth vertical connectors 31 to 34.

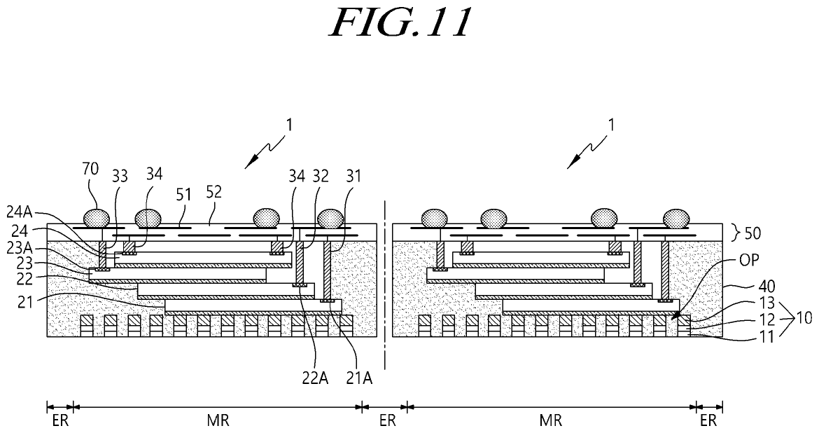

Referring to FIG. 11, a step of attaching external connection terminals 70, separating the carrier substrate 100, and individualizing semiconductor packages 1 may be performed.

Although not illustrated in detail, some of the redistribution lines 51 may include ball lands. The dielectric layer 52 may include openings which expose the ball lands. The external connection terminals 70 may be attached to the ball lands. The external connection terminals 70 may include solder balls.

After reducing the adhesion force of the debonding layer 110 using at least one of chemical processing and optical processing, the carrier substrate 100 may be removed and separated.

Thereafter, the redistribution layer 50 and the molding member 40 may be cut along a sawing line defined in the peripheral region ER through a sawing process. Because the heat dissipation member 10 does not exist in the peripheral region ER, a stress applied to a material during the sawing process may decrease, and occurrence of a burr may be mitigated or suppressed to obtain a clean cut surface.

Although some embodiments of the present disclosure have been described for illustrative purposes, those skilled in the art will appreciate that various modifications, additions, and/or substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the presented embodiments and the accompanying drawings.

What is claimed is:

1. A semiconductor package comprising:
a heat dissipation member having a plurality of through holes which pass through a first surface of the heat dissipation member;
a semiconductor chip disposed on the first surface of the heat dissipation member;
a vertical connector connected to the semiconductor chip;
a molding member sealing the semiconductor chip, sealing the vertical connector, and filling the plurality of through holes; and
a redistribution layer disposed on the molding member.

2. The semiconductor package according to claim 1, wherein the heat dissipation member comprises a material with a greater Young's modulus than the molding member.

3. The semiconductor package according to claim 1, wherein the molding member comprises an epoxy molding compound, and wherein the heat dissipation member comprises metal.

4. The semiconductor package according to claim 1, wherein the heat dissipation member comprises:
a barrier metal layer;
a seed metal layer disposed on the barrier metal layer; and
a plated metal layer disposed on the seed metal layer, the upper surface of the plated metal layer opposite the seed metal layer defining the first surface.

5. The semiconductor package according to claim 4, wherein the barrier metal layer comprises metal with a lower ionization tendency than the plated metal layer.

6. The semiconductor package according to claim 4, wherein
the barrier metal layer comprises at least one of Titanium (Ti), titanium-tungsten (TiW), and Nickel (Ni), and
the plated metal layer comprises copper (Cu).

7. The semiconductor package according to claim 4, wherein the plurality of through holes pass through the barrier metal layer, the seed metal layer, and the plated metal layer.

8. The semiconductor package according to claim 7, further comprising:
a fiducial mark disposed at the same height level as the plated metal layer.

9. The semiconductor package according to claim 8, wherein the fiducial mark is formed of the same material as the plated metal layer.

10. The semiconductor package according to claim 4, wherein the plurality of through holes pass through the plated metal layer, do not pass through the seed metal layer, and do not pass through the barrier metal layer.

11. The semiconductor package according to claim 4, wherein a thickness of the plated metal layer is greater than a sum of a thickness of the seed metal layer and a thickness of the barrier metal layer.

12. The semiconductor package according to claim 1, wherein the molding member does not to cover a second surface of the heat dissipation member which is opposite to the first surface.

13. The semiconductor package according to claim 1, wherein
the heat dissipation member comprises the first surface, a second surface which is opposite to the first surface, and outer side surfaces which connect an outer edge of the first surface and an outer edge of the second surface, and
the molding member surrounds the outer side surfaces of the heat dissipation member.

14. The semiconductor package according to claim 1, wherein
the molding member comprises a plurality of protrusions which fill the plurality of through holes, and
wherein side surfaces of the plurality of protrusions contact inner side surfaces of the heat dissipation member which are defined by the plurality of through holes.

15. The semiconductor package according to claim 1, wherein the semiconductor chip is attached to the heat dissipation member by an adhesive layer.

16. A method for manufacturing a semiconductor package, the method comprising:
forming, on a carrier substrate, a heat dissipation member having a plurality of through holes;
disposing a semiconductor chip on the heat dissipation member;
forming a vertical connector connected to the semiconductor chip;
forming a molding member which seals the semiconductor chip and the vertical connector and fills the plurality of through holes; and
forming a redistribution layer on the molding member.

17. The method according to claim 16, wherein the heat dissipation member comprises a material with a greater Young's modulus than the molding member.

18. The method according to claim 16, wherein the molding member comprises an epoxy molding compound, and the heat dissipation member comprises metal.

19. The method according to claim 16, wherein the forming of the heat dissipation member comprises:
forming a barrier metal layer on the carrier substrate;
forming a seed metal layer on the barrier metal layer;
forming a mask pattern having a mesh-shaped opening region on the seed metal layer; and
forming a plated metal layer on the seed metal layer exposed by the mask pattern.

20. The method according to claim 19, wherein the barrier metal layer comprises metal with a lower ionization tendency than the plated metal layer.

21. The method according to claim 19, wherein
the barrier metal layer comprises at least one of titanium (Ti), titanium-tungsten (TiW), and Nickel (Ni), and
the plated metal layer comprises copper (Cu).

22. The method according to claim 19, further comprising:
removing the mask pattern after the forming of the plated metal layer; and
etching the seed metal layer and the barrier metal layer using the plated metal layer as an etch mask.

23. The method according to claim 19, further comprising:
additionally forming a fiducial mark on the seed metal layer.

24. The method according to claim 23, wherein forming the plated metal layer includes forming the fiducial mark together with the plated metal layer.

25. The method according to claim 23, wherein disposing of the semiconductor chip includes determining a position of the semiconductor chip using the fiducial mark as a reference point.

26. The method according to claim 16, further comprising:
removing the carrier substrate after forming the redistribution layer; and
cutting the redistribution layer and the molding member along a sawing line.

27. The method according to claim 26, wherein
the heat dissipation member comprises a first surface on which the semiconductor chip is disposed, a second surface which is opposite to the first surface, and outer side surfaces which connect an outer edge of the first surface and an outer edge of the second surface, and
the sawing line is disposed outside the outer side surfaces of the heat dissipation member.
